(19) United States
(12) Patent Application Publication
(10) Pub. No.: US 2026/0371980 A1
(43) Pub. Date: Nov. 19, 2026

(54) METHOD FOR MANUFACTURING DEVICE CHIPS

(71) Applicant: DISCO CORPORATION, Tokyo (JP)

(72) Inventors: Kentaro ODANAKA, Tokyo (JP); Toshiyuki YOSHIKAWA, Tokyo (JP)

(21) Appl. No.: 19/644,741

(22) Filed: Apr. 10, 2026

(30) Foreign Application Priority Data
May 13, 2025 (JP) 2025-080383

(51) Int. Cl. H10P 58/00; H10P 34/42

(52) U.S. Cl. CPC H10P 58/20; H10P 34/42

(57) ABSTRACT

A method is for manufacturing device chips by dividing a workpiece on which devices are formed in regions defined by planned division lines, along the planned division lines. The method includes dividing the workpiece by cutting the workpiece with a cutting blade, along each of the planned division lines, from one surface of the workpiece; and, before the dividing, forming a guide layer for guiding extension of a crack generated upon cutting by the cutting blade, on a side of the other surface of the workpiece.

### CROSS-REFERENCE TO RELATED APPLICATION(S)

The present application claims priority to and incorporates by reference the entire contents of Japanese Patent Application No. 2025-080383 filed in Japan on May 13, 2025.

### BACKGROUND

The present disclosure relates to a method for manufacturing device chips.

As a method of manufacturing a semiconductor device, there is known a method of dividing a semiconductor wafer on which devices are formed in a plurality of regions defined by planned division lines, into chips by cutting the semiconductor wafer with a cutting blade along the planned division lines.

However, when the semiconductor wafer is cut by the cutting blade from a front surface side, a crack may extend from the cutting blade during cutting to reach a back surface side, and chipping exceeding a kerf width removed by the cutting blade may be formed (see JP H06-112310 A).

### SUMMARY

A method according to one aspect of the present disclosure is for manufacturing device chips by dividing a workpiece on which devices are formed in regions defined by planned division lines, along the planned division lines. The method includes: dividing the workpiece by cutting the workpiece with a cutting blade, along each of the planned division lines, from one surface of the workpiece; and before the dividing, forming a guide layer for guiding extension of a crack generated upon cutting by the cutting blade, on a side of the other surface of the workpiece.

### BRIEF DESCRIPTION OF THE DRAWINGS

FIG. 1 is a perspective view of a workpiece, illustrating the workpiece as a processing target of a method for manufacturing device chips, according to an embodiment; FIG. 2 is an enlarged cross-sectional view illustrating a main portion of the workpiece illustrated in FIG. 1; FIG. 3 is a flowchart illustrating a procedure of the method for manufacturing device chips, according to the embodiment; FIG. 4 is a partially cross-sectional side view illustrating a state of a film removal step; FIG. 5 is an enlarged cross-sectional view illustrating a part of the workpiece after the film removal step; FIG. 6 is a partially cross-sectional side view illustrating a state of a guide layer forming step; FIG. 7 is a cross-sectional view illustrating a first example of a guide layer; FIG. 8 is a cross-sectional view illustrating a second example of the guide layer; FIG. 9 is a cross-sectional view illustrating a third example of the guide layer; FIG. 10 is a partially cross-sectional side view illustrating a state of a division step; FIG. 11 is a cross-sectional view illustrating extension of a crack in the division step after forming the guide layer of the first example; and FIG. 12 is a cross-sectional view illustrating extension of a crack in the division step after forming the guide layer of the third example.

### DETAILED DESCRIPTION

An embodiment of the present disclosure will be described in detail with reference to the drawings. It is noted that the present invention is not limited to the contents described in the following embodiments. In addition, component elements described below include those readily conceivable by those skilled in the art and those substantially equivalent. Furthermore, configurations described below may be appropriately combined. Still furthermore, various omissions, substitutions, or modifications of the configurations may be made without departing from the gist of the present invention.

### Embodiments

### Workpiece

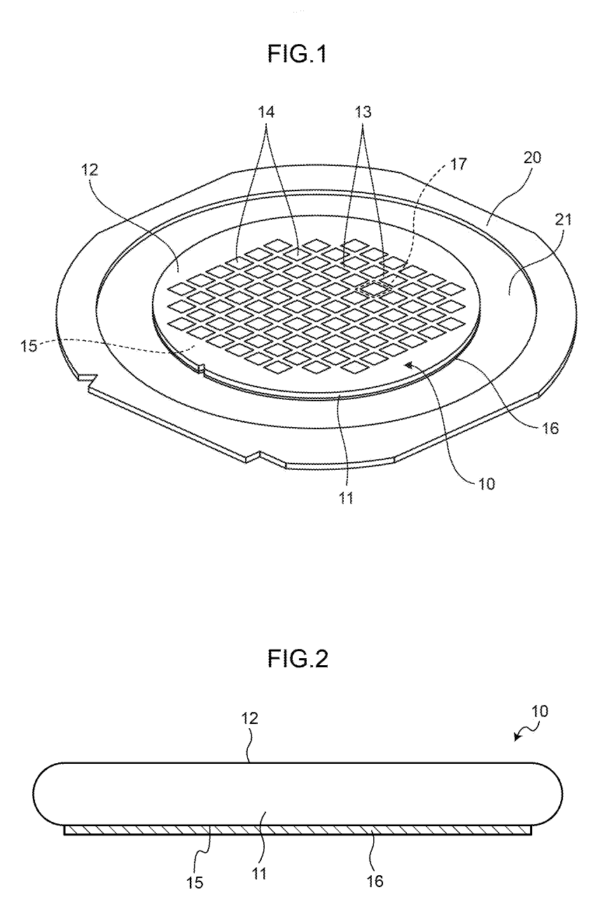

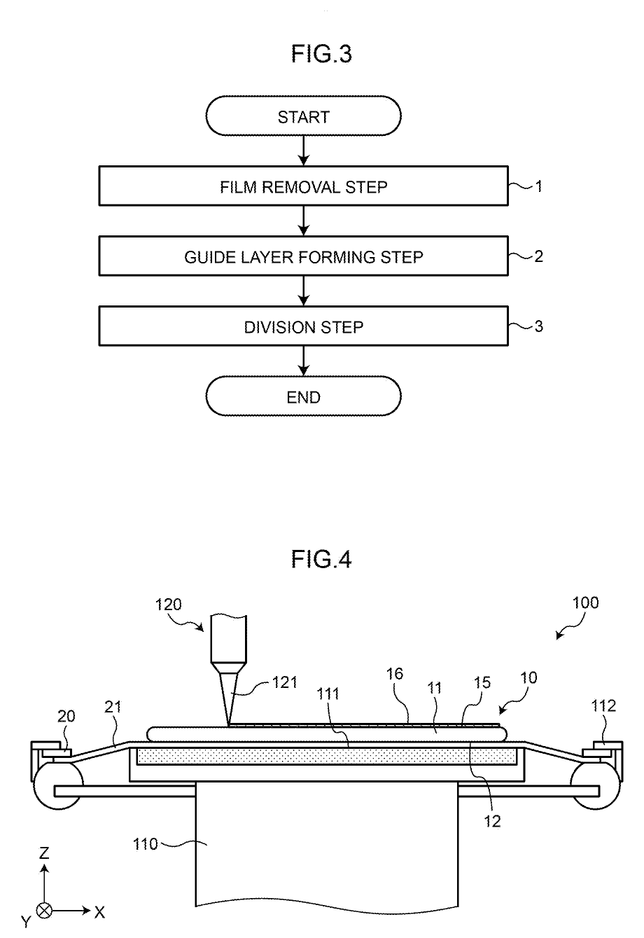

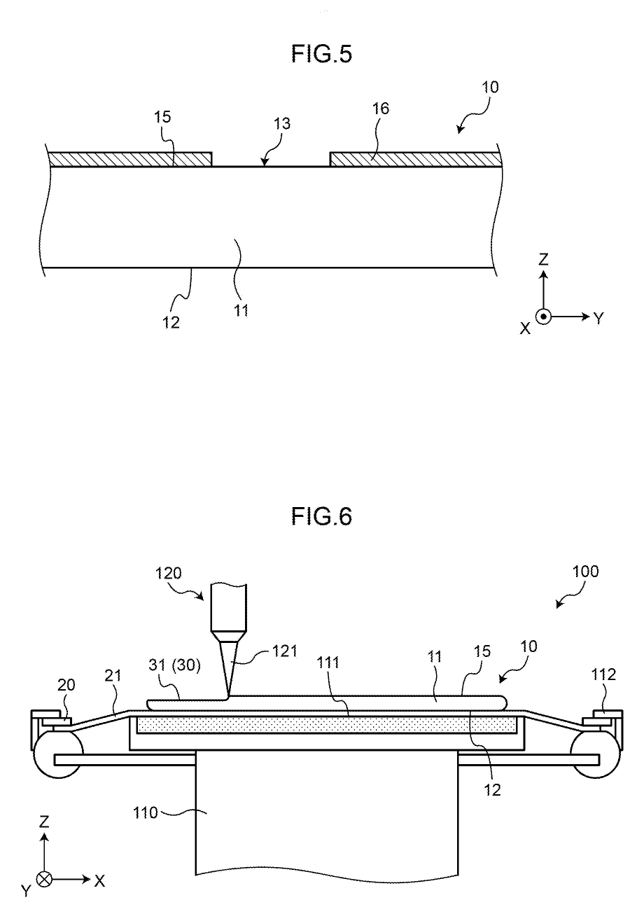

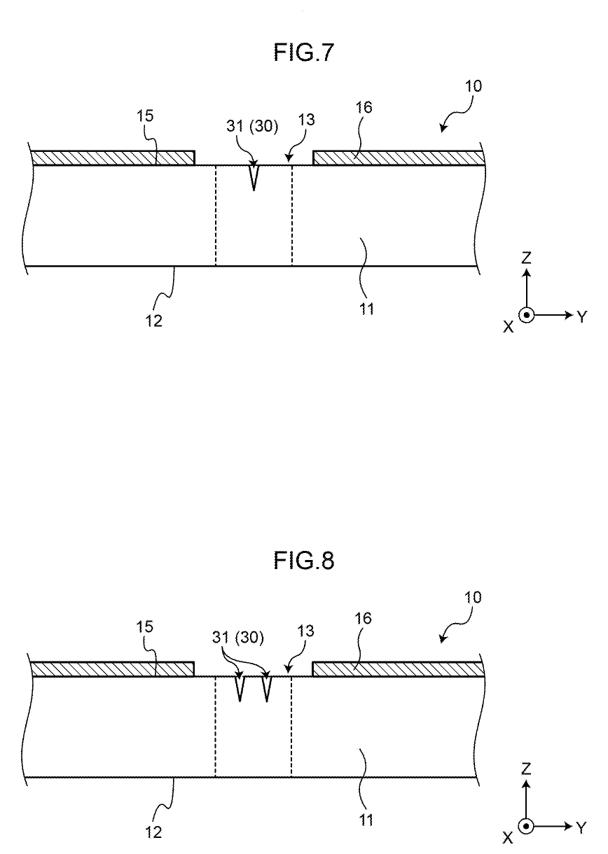

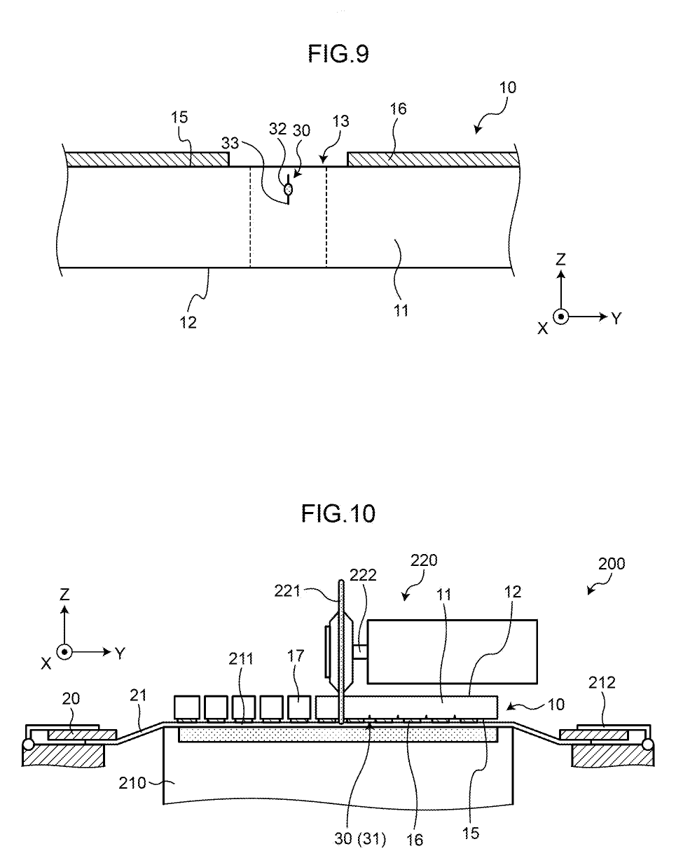

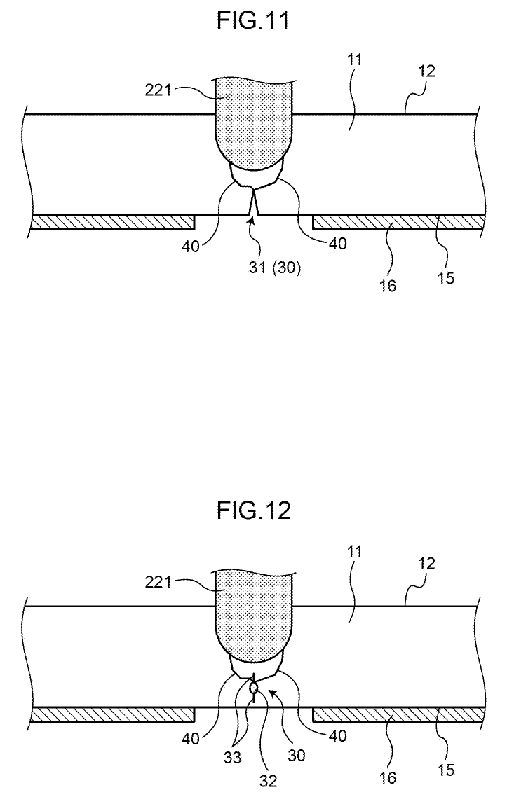

First, a workpiece 10 as a processing target in a method for manufacturing device chips, according to an embodiment of the present disclosure will be described with reference to the drawings. FIG. 1 is a perspective view of a workpiece, illustrating the workpiece as a processing target of the method for manufacturing device chips, according to the embodiment. FIG. 2 is an enlarged cross-sectional view illustrating a main portion of the workpiece illustrated in FIG. 1.

The workpiece 10 is, for example, a wafer such as a disk-shaped semiconductor wafer or an optical device wafer having a substrate 11 made of silicon (Si), silicon carbide (SiC), gallium nitride (GaN), gallium arsenide (GaAs), lithium tantalate (LiTaO3), or another semiconductor material. The workpiece 10 is, for example, a disk-shaped wafer having the substrate 11 made of a material such as sapphire (Al2O3), glass, or quartz. Examples of the glass include alkali glass, alkali-free glass, soda-lime glass, lead glass, borosilicate glass, quartz glass, and the like.

As illustrated in FIGS. 1 and 2, the workpiece 10 includes a plurality of planned division lines 13 that is set to form a grid shape on a front surface 12 of the substrate 11, and a device 14 that is formed in each of regions defined by the plurality of planned division lines 13. The device 14 is, for example, an integrated circuit such as an integrated circuit (IC) or a large scale integration (LSI), an image sensor such as a charge coupled device (CCD) or a complementary metal oxide semiconductor (CMOS), a micro electro mechanical systems (MEMS), or the like.

In the embodiment, a tape 21 that has a diameter larger than an outer diameter of the workpiece 10 and onto which an annular frame 20 is applied is applied to the front surface 12 or a back surface 15, and the workpiece 10 is transferred and processed while being supported in an opening of the frame 20. The frame 20 is an annular plate member made of metal or resin and having the opening larger than the outer diameter of the workpiece 10. The tape 21 has a sheet shape having an outer diameter larger than that of the opening of the frame 20, and is applied to a back surface side of the frame 20 so as to cover the opening of the frame 20. The tape 21 may include, for example, a base material layer made of a stretchable synthetic resin and an adhesive layer stacked on the base material layer and made of a stretchable and adhesive synthetic resin, or may be made of a thermoplastic resin without the adhesive layer.

The workpiece 10 has a thickness of, for example, approximately 50 μm to 775 μm. In the embodiment, the workpiece 10 is an SiC substrate with a thickness of 100 μm, having an Si surface on a side of the front surface 12 and a C surface on a side of the back surface 15, and includes a film 16 covering the back surface 15. The film 16 has a thickness of, for example, approximately 0.1 μm to 30 μm. In the embodiment, the film 16 is a metal film formed of gold (Au), copper (Cu), or the like and having a thickness of about 1 μm.

In the embodiment, in the workpiece 10, the substrate 11 is divided into the individual devices 14 along the planned division lines 13, and is divided into individual device chips 17. Note that the device chips 17 each have a square shape in the embodiment, but may have a rectangular shape.

Next, the method for manufacturing device chips according to the embodiment of the present disclosure will be described with reference to the drawings. FIG. 3 is a flowchart illustrating a procedure of the method for manufacturing device chips according to the embodiment. As illustrated in FIG. 3, the method for manufacturing device chips according to the embodiment includes a film removal step 1, a guide layer forming step 2, and a division step 3. Note that in the method for manufacturing device chips according to the embodiment, the workpiece 10 having the film 16 on the back surface 15 is the processing target, but the film removal step 1 may be omitted when the workpiece without the film 16 is the processing target.

### Film removal step 1

FIG. 4 is a partially cross-sectional side view illustrating a state of a film removal step. FIG. 5 is an enlarged cross-sectional view illustrating a part of the workpiece after the film removal step.

The film removal step 1 is performed before the guide layer forming step 2 is performed. The film removal step 1 is a step of removing the film 16 at least in regions along the planned division lines 13, in the film 16 formed on the other surface side of the workpiece 10. In the embodiment, the other surface is the back surface 15. The film removal step 1 of the embodiment is performed by a laser processing apparatus 100 illustrated in FIG. 4.

The laser processing apparatus 100 includes a holding table 110 and a laser beam irradiation unit 120. Furthermore, the laser processing apparatus 100 further includes a moving unit and a rotating unit, which are not illustrated, relatively moving the holding table 110 and the laser beam irradiation unit 120, an imaging unit, which is not illustrated, imaging the workpiece 10, a control unit controlling each of the configurations, and the like.

The laser processing apparatus 100 according to the embodiment is an apparatus that irradiates the workpiece 10 as the processing target with a laser beam 121 to process the workpiece 10. The processing of the workpiece 10 by the laser processing apparatus 100 is, for example, a modified layer forming process of forming a modified layer inside the workpiece 10, a grooving process of forming a groove in the front surface 12 or the back surface 15 of the workpiece 10, a cutting process of cutting the workpiece 10 along each of the planned division lines 13, or the like.

The holding table 110 holds the workpiece 10 on a holding surface 111 in a suction manner. The holding surface 111 is a flat surface parallel to a horizontal direction and has a disk shape. Around the holding table 110, a plurality of clamp members 112 that clamp the frame 20 supporting the workpiece 10 are arranged. The holding table 110 is relatively movable in an X-axis direction, a Y-axis direction, and a Z-axis direction with respect to at least a condenser of the laser beam irradiation unit 120 by the moving unit, which is not illustrated. Furthermore, the holding table 110 is rotatable about an axis parallel to the Z-axis direction by the rotating unit, which is not illustrated.

Note that in the following description, the X-axis direction is one direction on a horizontal plane. The Y-axis direction is a direction orthogonal to the X-axis direction on the horizontal plane. The Z-axis direction is a direction orthogonal to the X-axis direction and the Y-axis direction. In the laser processing apparatus 100 of the embodiment, a processing feed direction is in the X-axis direction, an indexing feed direction is in the Y-axis direction, and a focal point adjustment direction is in the Z-axis direction.

The laser beam irradiation unit 120 is a unit that irradiates the workpiece 10 held on the holding table 110 with the laser beam 121 pulsed. The laser beam irradiation unit 120 includes, for example, a laser oscillator, the condenser, and various optical elements. The laser oscillator oscillates the laser beam 121 having a predetermined wavelength for processing the workpiece 10. The condenser focuses and applies the laser beam 121 emitted from the laser oscillator to the workpiece 10 held on the holding surface 111 of the holding table 110.

In the film removal step 1, the side of the front surface 12 of the workpiece 10 is held on the holding surface 111 of the holding table 110 via the tape 21 in the suction manner, first. Next, each planned division line 13 is detected by imaging the workpiece 10 by the imaging unit, which is not illustrated, and alignment is performed to align the holding table 110 and the condenser of the laser beam irradiation unit 120 by the moving unit, which is not illustrated. Note that the imaging unit, which is not illustrated, is provided below the holding surface 111 of the holding table 110, and detects the planned division line 13 formed on the front surface 12 of the workpiece 10 through the holding surface 111 made of a transparent material such as glass.

In the film removal step 1, next, the laser beam 121 is applied from the side of the back surface 15 of the workpiece 10, while the planned division line 13 and a focal point of the laser beam 121 are relatively fed for processing along the processing feed direction (the X-axis direction) by the moving unit, which is not illustrated. Here, in the film removal step 1 of the embodiment, the laser beam 121 is a laser beam having a wavelength that is absorbable by the workpiece 10, and is, for example, an ultraviolet (UV) light.

Application of the laser beam 121 along the planned division line 13 in this manner removes the film 16 in a region along the planned division line 13, in the film 16 on the side of the back surface 15, as illustrated in FIG. 5.

### Guide layer forming step

FIG. 5 is an enlarged cross-sectional view illustrating a part of the workpiece after the film removal step. FIG. 6 is a partially cross-sectional side view illustrating a state of the guide layer forming step. FIG. 7 is a cross-sectional view illustrating a first example of a guide layer. Note that a region surrounded by a broken line, illustrated in FIG. 7, indicates a region removed by a cutting blade 221 (see FIG. 10) in the division step 3 described later.

The guide layer forming step 2 is performed before the division step 3 is performed. The guide layer forming step 2 is a step of forming a guide layer 30 for guiding extension of a crack 40 (see FIG. 11) generated upon cutting by the cutting blade 221, on the other surface side of the workpiece 10. In the embodiment, the other surface is the back surface 15. The guide layer forming step 2 of the embodiment is performed by the laser processing apparatus 100 illustrated in FIG. 6. The laser processing apparatus 100 illustrated in FIG. 6 is preferably the laser processing apparatus 100 used in the film removal step 1 illustrated in FIG. 4, but may be another laser processing apparatus 100.

Following the film removal step 1, in the workpiece 10, the side of the front surface 12 of the workpiece 10 is held on the holding surface 111 of the holding table 110 via the tape 21 in the suction manner. In the guide layer forming step 2, next, the planned division line 13 from which the film 16 has been removed is detected by imaging the workpiece 10 by the imaging unit, which is not illustrated, and alignment is performed to align the holding table 110 and the condenser of the laser beam irradiation unit 120 by the moving unit, which is not illustrated. Note that the imaging unit, which is not illustrated, may be provided below the holding surface 111 of the holding table 110 to detect the planned division line 13 formed on the front surface 12 of the workpiece 10 through the holding surface 111 made of a transparent material such as glass, or the imaging unit may be provided above the holding table 110 to detect the region from which the film 16 has been removed as the planned division line 13.

In the guide layer forming step 2, the laser beam 121 is applied from the side of the back surface 15 of the workpiece 10, while the planned division line 13 and a focal point of the laser beam 121 are relatively fed for processing along the processing feed direction (the X-axis direction) by the moving unit, which is not illustrated. Here, in the guide layer forming step 2 of the embodiment, the laser beam 121 is a laser beam having a wavelength that is absorbable by the workpiece 10, and is, for example, an ultraviolet ray.

Application of the laser beam 121 along the planned division line 13 in this manner forms a laser processing groove 31 along the planned division line 13, as the guide layer 30, in the region on the side of the back surface 15 from which the film 16 has been removed, as illustrated in FIG. 7. The laser processing groove 31 of the embodiment is a V-shaped groove decreasing in depth toward the outsides in a width direction of the planned division line 13. The laser processing groove 31 preferably has a depth of approximately 10 μm to 20 μm relative to the SiC substrate having a thickness of approximately 100 μm according to the embodiment. Furthermore, the laser processing groove 31 has a width smaller than the thickness of the cutting blade 221 (see FIG. 10) used to divide the workpiece 10 in the division step 3 which is described later, and is preferably removed by the cutting blade 221 in the division step 3.

Here, another example of the guide layer 30 will be described. FIG. 8 is a cross-sectional view illustrating a second example of the guide layer. As illustrated in FIG. 8, the guide layer 30 may be two laser processing grooves 31 arranged side by side in the width direction of the planned division line 13. For forming the laser processing grooves 31 configured in this way, for example, the laser beam irradiation unit 120 of the laser processing apparatus 100 preferably includes a splitting element that splits the laser beam 121 emitted from the laser oscillator, in the width direction of the planned division line 13. Furthermore, the number of rays of the laser beam 121 split in the width direction may be three or more, and the number of the laser processing grooves 31 may be three or more.

Furthermore, the guide layer 30 is not limited to the laser processing groove 31, and may be a processing groove formed by plasma processing, cutting, or the like. When the processing groove is formed by cutting, a cutting blade having a width smaller than that of the cutting blade 221 used in the division step 3, described later, is preferably used. In addition, the guide layer 30 is not limited to the processing groove, and may be a modified layer formed inside the substrate 11.

FIG. 9 is a cross-sectional view illustrating a third example of the guide layer. As illustrated in FIG. 9, as the guide layer 30, a modified layer 32 along the planned division line 13 and a crack 33 extending from the modified layer 32 may be formed in a portion closer to the side of the back surface 15 relative to the side of the front surface 12 in the substrate 11. The crack 33 preferably extends from the modified layer 32 and reaches the side of the back surface 15 of the substrate 11. In this configuration, in the guide layer forming step 2, the laser beam 121 is applied while the focal point of the laser beam 121 is positioned inside the substrate 11. The laser beam 121 is a laser beam having a wavelength that is transmittable through the workpiece 10, and is, for example, an infrared light. Furthermore, the laser beam 121 may be applied from the side of the back surface 15 of the workpiece 10 as in the forming of the laser processing groove 31, or may be applied from the side of the front surface 12 through the tape 21.

Note that the modified layer 32 means a region whose density, refractive index, mechanical strength, or another physical characteristic is different from that of the surrounding regions. The modified layer 32 is, for example, a melt processing region, a crack region, a breakdown region, a refractive index change region, a region in which these regions are mixed, and the like. The modified layer 32 has a mechanical strength and the like lower than those of the other portions of the workpiece 10. The crack 33 extends from the modified layer 32.

Division step

FIG. 10 is a partially cross-sectional side view illustrating a state of the division step. FIG. 11 is a cross-sectional view illustrating extension of a crack in the division step after forming the guide layer of the first example.

The division step 3 is a step of dividing the workpiece 10 by cutting the workpiece 10 with the cutting blade 221, along the planned division line 13, from one surface side. In the embodiment, the one surface is the front surface 12. The division step 3 of the embodiment is performed by a cutting device 200 illustrated in FIG. 10.

The cutting device 200 includes a holding table 210 and a cutting unit 220. Furthermore, the cutting device 200 further includes a cutting fluid supply unit supplying cutting water to a processing point, a moving unit and a rotating unit, which are not illustrated, relatively moving the holding table 210 and the cutting unit 220, an imaging unit imaging the workpiece 10, a control unit controlling each configuration, and the like.

The holding table 210 holds the workpiece 10 on a holding surface 211, in a suction manner. The holding surface 211 is a flat surface parallel to a horizontal direction and has a disk shape made of porous ceramic or the like. Around the holding table 210, a plurality of clamp members 212 that clamp the frame 20 supporting the workpiece 10 are arranged. The holding table 210 is relatively movable in an X-axis direction, a Y-axis direction, and a Z-axis direction with respect to the cutting unit 220 by the moving unit, which is not illustrated. Furthermore, the holding table 210 is rotatable about an axis parallel to the Z-axis direction by the rotating unit, which is not illustrated.

The cutting unit 220 is a unit that cuts the workpiece 10 held on the holding table 210. The cutting unit 220 includes the cutting blade 221 and a spindle 222. The cutting blade 221 is a processing tool for forming a cutting groove in the workpiece 10, and is a cutting abrasive product having a cutting edge obtained by securing diamond abrasives or cubic boron nitride (CBN) abrasives with bond such as a metal or a resin and formed into a considerably thin disk shape and annular shape. The spindle 222 is provided so as to be rotatable about an axis that is parallel to the horizontal direction and parallel to the indexing feed direction (the Y-axis direction) orthogonal to the processing feed direction (the X-axis direction), and has a front end to which the cutting blade 221 is coaxially mounted.

In the division step 3, the tape 21 is replaced first. Specifically, in the guide layer forming step 2, the tape 21 having been applied to the side of the front surface 12 of the workpiece 10 is separated, and a new tape 21 is applied to the side of the back surface 15 of the workpiece 10. Note that a method of separating the tape 21 and a method of applying the tape 21 may be performed by using known methods.

In the division step 3, next, the side of the back surface 15 of the workpiece 10 is held on the holding surface 211 of the holding table 210 via the tape 21 in the suction manner. Next, the planned division line 13 from which the film 16 has been removed is detected by imaging the workpiece 10 by the imaging unit, which is not illustrated, and alignment is performed to align the holding table 210 and the cutting blade 221 by the moving unit, which is not illustrated. Specifically, the processing point of the cutting blade 221 is positioned above the planned division line 13 of the workpiece 10.

In the division step 3, next, supply of a cutting fluid toward the processing point of the cutting blade 221 is started, and rotation of the spindle 222 is started. Next, the workpiece 10 is cut by the cutting edge of the cutting blade 221 from the side of the front surface 12, while the holding table 210 is fed for processing in the X-axis direction. Therefore, the workpiece 10 is divided along the planned division lines 13.

At this time, as illustrated in FIG. 11, the crack 40 is generated from the vicinity of the bottom of the cutting groove cut by the cutting blade 221. The crack 40 extends toward the guide layer 30 formed in advance in the guide layer forming step 2. In other words, extension of the crack 40 is guided by the guide layer 30. Therefore, it is possible to suppress the crack 40 from extending outside a kerf width removed by the cutting blade 221.

FIG. 12 is a cross-sectional view illustrating extension of the crack in the division step after forming the guide layer of the third example. As illustrated in FIG. 12, also when the modified layer 32 and the crack 33 are formed as the guide layer 30, the crack 40 generated upon cutting by the cutting blade 221 extends toward the guide layer 30. In other words, extension of the crack 40 is guided by the guide layer 30. Therefore, it is possible to suppress the crack 40 from extending outside a kerf width removed by the cutting blade 221.

As described above, in the method for manufacturing device chips according to the embodiment, the guide layer 30 is formed in advance in a surface opposite to a surface where the workpiece 10 is cut by the cutting blade 221, whereby the crack 40 extending from the cutting blade 221 is guided to the guide layer 30. In this way, guiding the crack 40 extending from the cutting blade 221 during cutting to the guide layer 30 makes it possible to suppress the crack 40 from extending outside the kerf width removed by the cutting blade 221, thus suppressing the occurrence of chipping.

According to the present disclosure, it is possible to suppress backside chipping.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method for manufacturing device chips by dividing a workpiece on which devices are formed in regions defined by planned division lines, along the planned division lines, the method comprising:
dividing the workpiece by cutting the workpiece with a cutting blade, along each of the planned division lines, from one surface of the workpiece; and
before the dividing, forming a guide layer for guiding extension of a crack generated upon cutting by the cutting blade, on a side of the other surface of the workpiece.

2. The method according to claim 1, wherein the forming includes forming a laser processing groove by applying a laser beam having a wavelength that is absorbable by the workpiece.

3. The method according to claim 2, wherein the guide layer includes a V-shaped groove decreasing in depth toward the outsides in a width direction of the planned division line, on the side of the other surface.

4. The method according to claim 2, wherein
the guide layer includes a groove having a width smaller than a thickness of the cutting blade, on the side of the other surface, and
the dividing includes removing the groove by the cutting blade.

5. The method according to claim 2, further comprising, before the forming, removing a film at least in a region along the planned division line,
wherein the film is formed on the side of the other surface of the workpiece.

6. The method according to claim 1, wherein the workpiece includes a SiC substrate.
